(19) United States
(12) Patent Application Publication
(10) Pub. No.: US 2011/0140778 A1
(43) Pub. Date: Jun. 16, 2011

(54) AUTOMATIC GAIN CONTROL METHOD AND APPARATUS

(75) Inventors: Woong CHO, Daejeon (KR); Hyun Kyun Choi, Daejeon (KR); Hyun Seo Oh, Daejeon (KR)

(73) Assignee: Electronics and Telecommunications Research Institute, Daejeon (KR)

(21) Appl. No.: 12/961,539

(22) Filed: Dec. 7, 2010

(30) Foreign Application Priority Data
Dec. 15, 2009 (KR) 10-2009-0124882
Apr. 21, 2010 (KR) 10-2010-0037035

(51) Int. Cl. H03G 3/20

(52) U.S. Cl. 330/129

(57) ABSTRACT

An automatic gain control method of a receiving apparatus is provided. The automatic gain control method includes low-noise amplifying a signal using a first gain value, amplifying the low-noise amplified signal to a second gain value, determining the first gain value using a strength of the low-noise amplified signal, and determining the second gain value using the signal amplified to the second gain value. Accordingly, the reliability of the automatic gain control may be guaranteed.

### CROSS-REFERENCE TO RELATED APPLICATION

This application claims priority to and the benefit of Korean Patent Application Nos. 10-2009-0124882 and 10-2010-0037035 filed in the Korean Intellectual Property Office on Dec. 15, 2009 and Apr. 21, 2010, the entire contents of which are incorporated herein by reference.

### BACKGROUND OF THE INVENTION

(a) Field of the Invention

The present invention relates to an automatic gain control method and apparatus. More particularly, the present invention relates to an automatic gain control method and apparatus in a communication environment according to an orthogonal frequency division multiplexing (OFDM) scheme.

(b) Description of the Related Art

In general, a signal processing apparatus performs automatic gain control (AGC) to reduce a reciprocal modulation phenomenon and prevent a saturation phenomenon at its amplification terminal. In particular, a receiving apparatus in a mobile communication system uses the automatic gain control to obtain a signal having a desired level from an inputted signal having an irregular level

That is, when the strength of an input signal is larger than a reference value, the automatic gain control lowers the gain value to prevent the saturation of the signal. When the strength of the input signal is smaller than the reference value, the automatic gain control raises the gain value so that the signal can have a constant strength.

The automatic gain control scheme is used in most mobile communication systems as well as wireless local area network (WLAN) systems employing an OFDM standard. In the existing WLAN systems, the automatic gain control was considered only for situations where a communication apparatus remaining stationary or moving at low speed receives a signal. However, the automatic gain control should also be considered for situations where a communication apparatus mounted in a vehicle travelling at high speed receives a signal. When a communication apparatus travels at high speed, a received signal may be quickly changed. Therefore, there is a need for a method of performing automatic gain control with high reliability and stability even when a communication apparatus is on the move at high speed.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provides an automatic gain control method and apparatus having advantages of guaranteeing the reliability of automatic gain control in a communication environment where a communication device remains stationary or moves at low or high speed.

An exemplary embodiment of the present invention provides an automatic gain control method of a receiving apparatus, including: low-noise amplifying a signal using a first gain value; amplifying the low-noise amplified signal to a second gain value; determining the first gain value using a strength of the low-noise amplified signal; and determining the second gain value using the signal amplified to the second gain value.

Another embodiment of the present invention provides an automatic gain control apparatus including: a receiving unit that receives a radio frequency signal; a low-noise amplifier that amplifies the signal using a first gain value; a signal strength indicator that indicates a strength of a signal outputted from the low-noise amplifier, a variable gain amplifier that amplifies a signal outputted from the low-noise amplifier using a second gain value; and an automatic gain controller that determines the first gain value using a signal outputted from the signal strength indicator and determines the second gain value using a signal outputted from the variable gain amplifier.

### BRIEF DESCRIPTION OF THE DRAWINGS

FIG. 1 is a view schematically illustrating an automatic gain control apparatus according to an exemplary embodiment of the present invention;

FIG. 2 is a view illustrating an automatic gain control block according to an exemplary embodiment of the present invention;

FIG. 3 is a flowchart illustrating a method of performing automatic gain control using an automatic gain control apparatus according to an exemplary embodiment of the present invention; and

FIG. 4 is a flowchart illustrating in detail a method of performing automatic gain control by an automatic gain control block according to an exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In specification, In addition, unless explicitly described to the contrary, the word “comprise” and variations such as “comprises” or “comprising”, will be understood to imply the inclusion of stated elements but not the exclusion of any other elements.

In a wireless communication environment, the strength of a received signal varies with the position of a receiving terminal. Particularly in a communication environment where a receiving terminal is on the move, the strength of a received signal is not regular and the characteristics of the received signal are changed depending on ambient conditions and moving speed. Accordingly, the receiving terminal needs to be subjected to automatic gain control (AGC) with respect to the received signal. An automatic gain control apparatus or an automatic gain control circuit that performs automatic gain control transfers a signal having a constant level to a modem terminal irrespective of the strength of a signal received at a receiving terminal.

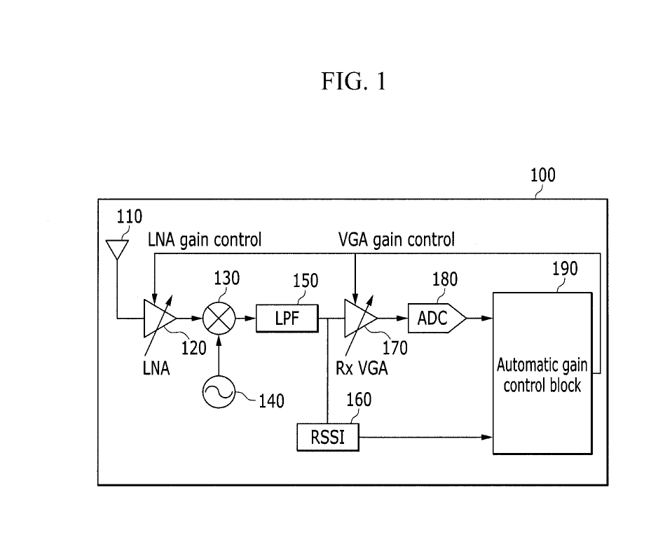

FIG. 1 is a view schematically illustrating an automatic gain control apparatus according to an exemplary embodiment of the present invention.

Referring to FIG. 1, an automatic gain control apparatus 100 includes a signal receiving unit 110, a low-noise amplifier (LNA) 120, a mixer 130, a local oscillator (LO) 140, a low pass filter (LPF) 150, a received signal strength indicator (RSSI) 160, a received signal variable gain amplifier (Rx VGA) 170, an analog-digital converter 180, and an automatic gain control block 190.

The signal receiving unit 110 receives a radio frequency (RF) signal and transfers the received RF signal to the low-noise amplifier 120. The RF signal used for automatic gain control may include a short training symbol during the preamble section of an OFDM signal. The low-noise amplifier 120 performs low noise amplification on the received RF signal using an LNA gain value. The mixer 130 mixes the RF signal outputted from the low-noise amplifier 120 with a signal having a predetermined frequency that is supplied from the local oscillator 140 to generate a baseband signal. The RF signal converted to have a baseband passes through the low pass filter 150. The RF signal having passed through the low pass filter 150 is amplified by the received signal variable gain amplifier 170 using a VGA value.

The RF signal having passed through the low pass filter 150 is transferred to the automatic gain control block 190 via the received signal strength indicator 160. The RF signal amplified by the received signal variable gain amplifier 170 is converted to digital values by the analog-digital converter 180 and then transferred to the automatic gain control block 190.

The automatic gain control block 190 determines an LNA gain value using the strength of the RF signal low-noise amplified by the low-noise amplifier 120. The automatic gain control block 190 determines a VGA gain value using the RF signal amplified by the received signal variable gain amplifier 170.

As such, the automatic gain control apparatus 100 performs automatic gain control on a received signal based on the VGA gain value and the LNA gain value outputted from the automatic gain control block 190. Accordingly, the automatic gain control apparatus 100 may obtain a reliable and stable automatic gain control result. A method of performing automatic gain control by the automatic gain control block 190 will now be described in greater detail.

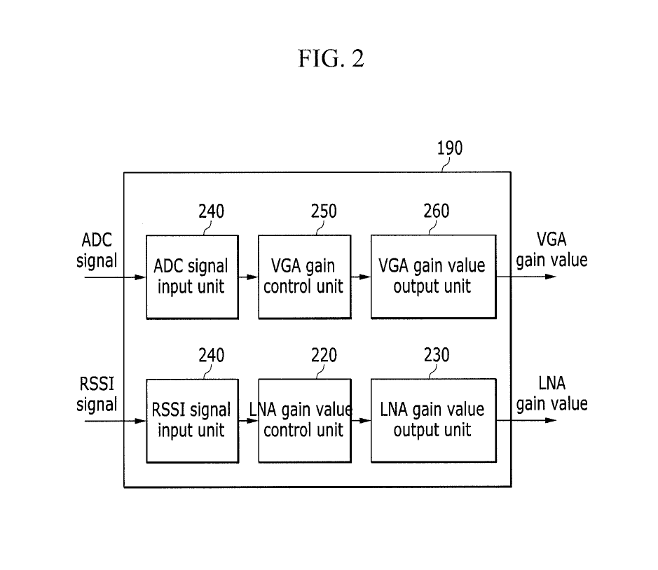

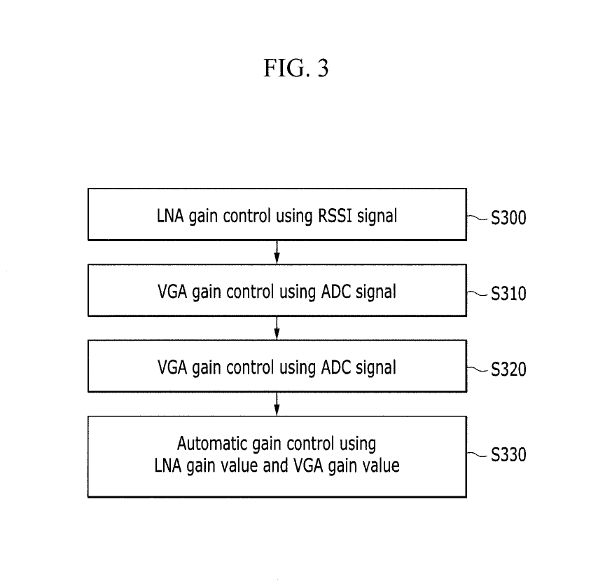

FIG. 2 is a view illustrating an automatic gain control block according to an exemplary embodiment of the present invention, and FIG. 3 is a flowchart illustrating a method of performing automatic gain control using an automatic gain control apparatus according to an exemplary embodiment of the present invention.

Referring to FIG. 2, the automatic gain control block 190 includes a RSSI signal input unit 210, an LNA gain control unit 220, an LNA gain value output unit 230, an ADC signal input unit 240, a VGA gain control unit 250, and a VGA gain value output unit 260.

Referring to FIGS. 2 and 3, the LNA gain control unit 220 performs LNA gain control using a RSSI signal received by the RSSI signal input unit 210 (S300). The ‘RSSI signal’ herein means the received signal strength indicator shown in FIG. 1 that has been amplified by the low-noise amplifier 120 and transferred to the automatic gain control block 190 via the received signal strength indicator 160. The RSSI signal is inputted as voltage values and the inputted voltage values are converted to digital values by an analog-digital conversion unit (not shown). The RSSI signal converted to the digital values is used for LNA gain control.

The VGA gain control unit 250 performs VGA gain control using an ADC signal received by the ADC signal input unit 240 (S310). The ‘ADC signal’ herein means the RF signal shown in FIG. 1 that has been amplified by the low-noise amplifier 120 and the received signal variable gain amplifier 170, converted to the digital values by the analog-digital converter 180, and then transferred to the automatic gain control block 190.

Next, the LNA gain value output unit 230 and the VGA gain value output unit 260 output a LAN gain value and a VGA gain value, respectively (S320), and the automatic gain control apparatus performs automatic gain control using the LAN gain value and the VGA gain value (S330).

The RSSI does not pass through the received signal variable gain amplifier 170 shown in FIG. 1. Accordingly, when the RSSI signal does not have a large range of voltage values, it is difficult to exactly estimate the signal. Accordingly, the RSSI signal is substantially used to determine an LNA gain value that controls a large gain value. The ADC signal may have a high-resolution power value thanks to an accurate ADC element and the variable gain amplifier may have various gain values depending on predefined accuracy. Accordingly, the VGA gain value may be accurately determined based on the ADC signal. That is, the automatic gain control apparatus performs coarse gain control based on the RSSI signal and accurate gain control based on the ADC signal.

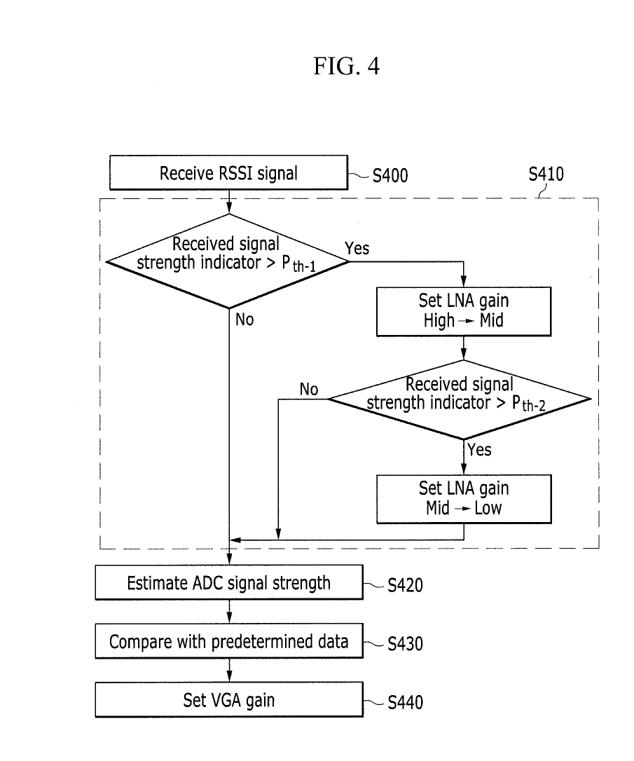

FIG. 4 is a flowchart illustrating in detail a method of performing automatic gain control by an automatic gain control block according to an exemplary embodiment of the present invention.

Referring to FIG. 4, the automatic gain control block receives a RSSI signal (S400) and controls the LNA gain using the RSSI signal (S410). The RSSI signal may be a received signal strength indicator for a received signal subjected to a low noise amplification process. The LNA gain value may be determined as one of a predetermined number of different gain values. For example, the LNA gain value may be set to be one of high, medium, and low values. The difference between the high and medium gain values or between the medium and low gain values may be 20 dB.

For example, the LNA gain value may be initially set high to control the LNA gain using the RSSI signal. The received signal strength indicator is compared with a predetermined reference signal strength 1. When the received signal strength indicator is not more than the reference signal strength 1, the LNA gain value is maintained and a next step is performed for VGA gain control. When the received signal strength indicator is more than the reference signal strength 1, the LNA gain value is lowered to a medium value. When the LNA gain value is lowered by one level, the received signal strength indicator is compared with a predetermined reference signal strength 2. When the received signal strength indicator is not more than the reference signal strength 2, the LNA gain value is maintained and a next step is performed for VGA gain control. When the received signal strength indicator is more than the reference signal strength 2, the LNA gain value is lowered to a low value and a next step is performed for VGA gain control.

Next, the automatic gain control block estimates the strength of the received ADC signal (S420). The strength of the ADC signal may have an electric power value. The estimated strength of the ADC signal is compared with predetermined data (S430) and the VGA gain is controlled based on the comparison result (S440). The predetermined data includes a gain value defined corresponding to the signal strength. Accordingly, the automatic gain control block controls the VGA gain using the signal strength and gain value corresponding to the ADC signal strength.

As such, the automatic gain control block coarsely controls the LNA gain value using the RSSI signal at the first step and accurately controls the VGA gain value using the ADC signal at the second step, thus allowing for stable and reliable automatic gain control.

According to an embodiment of the present invention, the reliability of automatic gain control may be guaranteed. In particular, even when a communication mounted in a vehicle moves fast, an automatic gain control effect may be stably obtained.

The above-mentioned exemplary embodiments of the present invention are not embodied only by an apparatus and method. Alternatively, the above-mentioned exemplary embodiments may be embodied by a program performing functions, which correspond to the configuration of the exemplary embodiments of the present invention, or a recording medium on which the program is recorded.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An automatic gain control method of a receiving apparatus, comprising:
receiving a signal;
low-noise amplifying the signal using a first gain value;
amplifying the low-noise amplified signal using a second gain value;
determining the first gain value using a strength of the low-noise amplified signal; and
determining the second gain value using the signal amplified using the second gain value.

2. The automatic gain control method of claim 1, wherein:
determining the first gain value includes,
determining a received signal strength indicator of the low-noise amplified signal, and
controlling the first gain value using the received signal strength indicator.

3. The automatic gain control method of claim 2, wherein:
controlling the first gain value includes,
comparing the received signal strength indicator with a reference signal strength, and
lowering the first gain value when the received signal strength indicator is more than the reference signal strength and maintaining the first gain value when the received signal strength indicator is not more than the reference signal strength.

4. The automatic gain control method of claim 3, wherein:
the first gain value is determined to be any one of a certain number of different gain values.

5. The automatic gain control method of claim 2, wherein:
determining the first gain value further includes,
converting the received signal strength indicator to digital values prior to controlling the first gain value.

6. The automatic gain control method of claim 1, further comprising:
converting the signal amplified using the second gain value to digital values prior to determining the second gain value.

7. The automatic gain control method of claim 1, wherein:
determining the second gain value includes,
comparing the signal amplified using the second gain value with predetermined data to control the second gain value.

8. An automatic gain control apparatus comprising:
a receiving unit that receives a radio frequency signal;
a low-noise amplifier that amplifies the signal using a first gain value;
a signal strength indicator that indicates a strength of a signal outputted from the low-noise amplifier,
a variable gain amplifier that amplifies a signal outputted from the low-noise amplifier using a second gain value; and
an automatic gain controller that determines the first gain value using a signal outputted from the signal strength indicator and determines the second gain value using a signal outputted from the variable gain amplifier.

9. The automatic gain control apparatus of claim 8, wherein:
the automatic gain controller compares the signal outputted from the signal strength indicator with a reference signal strength and lowers the first gain value when the signal outputted from the signal strength indicator is more than the reference signal strength and maintains the first gain value when the signal outputted from the signal strength indicator is not more than the reference signal strength.

10. The automatic gain control apparatus of claim 9, wherein:
the first gain value is determined to be any one of a certain number of different gain values.

11. The automatic gain control apparatus of claim 9, wherein:
the signal outputted from the signal strength indicator is converted into digital values and then compared with the reference signal strength.

12. The automatic gain control apparatus of claim 8, further comprising:
an analog-digital converter that converts the signal outputted from the variable gain amplifier to digital values before the automatic gain controller determines the second gain value.

13. The automatic gain control apparatus of claim 8, wherein:
the automatic gain controller compares the signal outputted from the variable gain amplifier with predetermined data to determine the second gain value.

14. The automatic gain control apparatus of claim 8, wherein:
the radio frequency signal is a training symbol during a preamble section included in an orthogonal frequency division multiplexing (OFDM) signal.

15. The automatic gain control apparatus of claim 8, further comprising:
a mixer that mixes the signal outputted from the low-noise amplifier with a signal having a predetermined frequency supplied from a local oscillator to generate a baseband signal.
